(19) United States
(12) Patent Application Publication
(10) Pub. No.: US 2026/0262555 A1
(43) Pub. Date: Sep. 3, 2026

(54) SEMICONDUCTOR DEVICE AND METHOD FOR MANUFACTURING THE SAME

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Shota HARADA, Nisshin-shi (JP); Takahiko YOSHIDA, Nisshin-shi (JP); Masaru NAGAO, Nisshin-shi (JP)

(21) Appl. No.: 19/538,017

(22) Filed: Feb. 12, 2026

(30) Foreign Application Priority Data
Mar. 3, 2025 (JP) 2025-033117

(51) Int. Cl. H10W 90/00; H10W 74/10

(52) U.S. Cl. CPC H10W 90/724; H10W 74/111; H10W 90/754; H10W 90/756

(57) ABSTRACT

A semiconductor device includes a semiconductor element, a circuit chip and a molded resin. The semiconductor element has a sensor portion that outputs a signal corresponding to a physical quantity applied thereto. The circuit chip has an electrical connection portion electrically connected to the semiconductor element. The molded resin has a housing portion that defines a space for housing the semiconductor element, a covering portion that covers a part of the circuit chip in the housing portion, and an abutting portion that protrudes from the covering portion and has an abutting surface. The semiconductor element is mounted on the abutting surface above the circuit chip. The semiconductor element and the electrical connection portion are exposed from the molded resin in the housing portion.

### CROSS REFERENCE TO RELATED APPLICATION

The present application claims the benefit of priority from Japanese Patent Application No. 2025-033117 filed on March 3, 2025. The entire disclosure of the above application is incorporated herein by reference.

### TECHNICAL FIELD

The present disclosure relates to a semiconductor device and a method for manufacturing the same.

### BACKGROUND

Conventionally, semiconductor devices having a structure in which a semiconductor element having a sensor portion that outputs a signal corresponding to a physical quantity applied from the outside is mounted on a mounting substrate and the semiconductor element is sealed, are known. For this type of semiconductor device, it is required to reduce the influence on the semiconductor element of deformation of the mounting substrate, stress due to the sealing structure and the like, from the viewpoint for stabilizing the output signal of the semiconductor element. As a structure for alleviating the influence of stress on such a semiconductor element, for example, a semiconductor device having a double molded structure has been proposed.

In the semiconductor device having the double molded structure, a part of a semiconductor element having a sensor portion is covered with a gel region, and both the semiconductor element and the gel region are covered with a plastic casing.

### SUMMARY

According to an aspect of the present disclosure, a semiconductor device includes a semiconductor element, a circuit chip and a molded resin. The semiconductor element has a sensor portion that outputs a signal corresponding to a physical quantity applied thereto. The circuit chip has an electrical connection portion electrically connected to the semiconductor element. The molded resin may have a housing portion that defines a space for housing the semiconductor element, a covering portion that covers a part of the circuit chip in the housing portion, and an abutting portion that protrudes from the covering portion and has an abutting surface. The semiconductor element may be mounted on the abutting surface above the circuit chip. The semiconductor element and the electrical connection portion may be exposed from the molded resin in the housing portion.

### BRIEF DESCRIPTION OF DRAWINGS

Objects, features and advantages of the present disclosure will become more apparent from the following detailed description made with reference to the accompanying drawings, in which like parts are designated by like reference numbers and in which:

FIG. 1 is a cross-sectional view of a semiconductor device according to a first embodiment;

FIG. 2 is a plan view showing a configuration inside a housing portion of the semiconductor device shown in FIG. 1;

FIG. 3A is a cross-sectional view showing a process in a manufacturing process of the semiconductor device shown in FIG. 1;

FIG. 3B is a cross-sectional view showing a process subsequent to the process shown in FIG. 3A;

FIG. 3C is a cross-sectional view showing a process subsequent to the process show in FIG. 3B;

FIG. 3D is a cross-sectional view showing a process subsequent to the process show in FIG. 3C;

FIG. 3E is a cross-sectional view showing a process subsequent to the process show in FIG. 3D;

FIG. 3F is a cross-sectional view showing a process subsequent to the process show in FIG. 3E;

FIG. 3G is a cross-sectional view showing a process subsequent to the process show in FIG. 3F;

FIG. 3H is a cross-sectional view showing a process subsequent to the process show in FIG. 3G;

FIG. 4 is a cross-sectional view of a semiconductor device according to a second embodiment;

FIG. 5 is a plan view showing an example of a structure of an abutting portion in the semiconductor device shown in FIG. 4;

FIG. 6 is a plan view showing a configuration inside a housing portion of a semiconductor device according to a third embodiment;

FIG. 7 is a cross-sectional view taken along a line VII-VII in FIG. 6;

FIG. 8 is a plan view showing a configuration inside a housing portion of a semiconductor device according to a fourth embodiment; and

FIG. 9 is a cross-sectional view taken along a line IX-IX in FIG. 8.

### DETAILED DESCRIPTION

In recent years, there has been a demand for miniaturization of semiconductor devices, and for example, package structures such as QFN and LGA have been adopted in the semiconductor devices. QFN and LGA are abbreviations for Quad Flat Non-leaded package and Land Grid Array, respectively. Although this type of package structure provides advantages in terms of miniaturization and cost reduction, it does not have a stress-relief structure like the double molded structure described above, making it difficult to ensure the stability of output signal from a semiconductor element. Furthermore, when the components of a semiconductor device are arranged at high density for miniaturization, the distance between the semiconductor element and a component that generates a large amount of heat, such as a circuit chip equipped with an application-specific integrated circuit (ASIC) becomes short. As a result, the output signal from the semiconductor element may be disturbed due to the influence of heat.

The present disclosure provides a semiconductor device including a semiconductor element with a sensor portion, which is reduced in size and capable of reducing stress to the semiconductor element and thermal influence, and a method for manufacturing the semiconductor device.

According to an aspect of the present disclosure, a semiconductor device includes a semiconductor element, a circuit chip and a molded resin. The semiconductor element has a sensor portion that outputs a signal corresponding to a physical quantity applied thereto. The circuit chip has an electrical connection portion electrically connected to the semiconductor element. The molded resin has a housing portion that defines a space for housing the semiconductor element, a covering portion that covers a part of the circuit chip in the housing portion, and an abutting portion that protrudes from the covering portion and has an abutting surface. The semiconductor element is mounted on the abutting surface above the circuit chip. The semiconductor element and the electrical connection portion are exposed from the molded resin in the housing portion.

In such a semiconductor device, the circuit chip and the semiconductor element are arranged in a stacked manner in the housing portion formed in the molded resin. The circuit chip is covered by the covering portion and the abutting portion of the molded resin, and the semiconductor element is disposed on the abutting portion. In this semiconductor device, the semiconductor element is exposed from the molded resin in the housing portion. Thus, the influence of stress on the semiconductor element is alleviated. In addition, since the semiconductor element is disposed above the circuit chip via the abutting portion, it is possible to reduce the semiconductor device in size and also reduce the thermal influence on the semiconductor element.

According to an aspect of the present disclosure, it is a method for manufacturing a semiconductor device that includes: a semiconductor element having a sensor portion that outputs a signal corresponding to a physical quantity applied thereto; a circuit chip having an electrical connection portion that is electrically connected to the semiconductor element; and a molded resin including a housing portion that defines a space for housing the semiconductor element, a covering portion that covers a part of the circuit chip in the housing portion, and an abutting portion that protrudes from the covering portion and has an abutting surface, in which the semiconductor element is mounted on the abutting surface above the circuit chip. The method for manufacturing the semiconductor device includes: forming the molded resin covering the part of the circuit chip using a mold; and after the forming of the molded resin, mounting the semiconductor element on the abutting surface. The mold, which is used in the forming the molded resin, has a protrusion protruding toward the circuit chip, a depressed portion provided on the protrusion and recessed away from the circuit chip, and a pressing portion provided on the protrusion and coming into contact with the electrical connection portion. The forming of the molded resin using the mold includes: forming the housing portion and the abutting portion of the molded resin by the protrusion and the depressed portion of the mold; and causing the electrical connection portion to be exposed in the housing portion from the molded resin.

In such a method, it is possible to produce the semiconductor device in which the semiconductor element is disposed on the circuit chip via the abutting portion of the molded resin, the semiconductor element is exposed from the molded resin in the housing portion, and stress and thermal influence on the semiconductor element are reduced, as well as a physical size is reduced.

Hereinafter, embodiments of the present disclosure will be described with reference to the drawings. In the following descriptions, identical or equivalent parts are denoted by the same reference numerals throughout the embodiments. When only some of the constituent elements of an embodiment are described, the constituent elements described in the preceding embodiment can be applied to the other constituent elements. The following embodiments can be partially combined with each other even if such a combination is not explicitly described as long as there is no hindrance in such a combination.

### First Embodiment

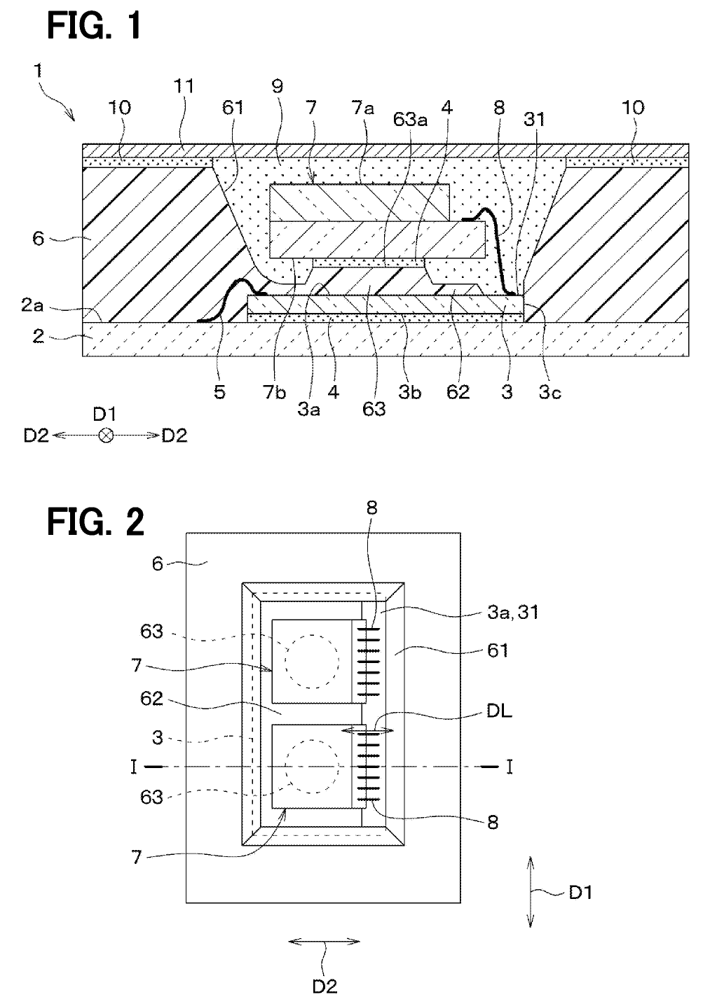

A semiconductor device 1 according to a first embodiment will be described. As shown in FIG. 1, for example, the semiconductor device 1 of the present embodiment includes a mounting substrate 2, a circuit chip 3, an adhering material 4, wires 5 and 8, a molded resin 6, a semiconductor element 7, a gel 9, a bonding material 10, and a lid member 11. The semiconductor device 1 is, for example, suitable for use in an in-vehicle application mounted in a vehicle, such as an automobile, but may of course also be used in other applications.

The mounting substrate 2 is a substrate on which the circuit chip 3 is mounted, and is, for example, a PCB. PCB is an abbreviation for printed circuit board. The mounting substrate 2 has, for example, a patterned wiring (not shown) that is electrically connected to the circuit chip 3, allowing electrical communication between an external power supply and the circuit chip 3 and the semiconductor element 7. The mounting substrate 2 has one surface 2a on which the circuit chip 3 is mounted via the adhering material 4, and the one surface 2a is covered with a molded resin 6. For example, the mounting substrate 2 is a plate having a substantially rectangular shape when viewed in a direction normal to the one surface 2a.

Hereinafter, for convenience of explanation, a state of the semiconductor device 1 or component(s) mounted thereon viewed in the direction normal to the one surface 2a of the mounting substrate 2 will be referred to as the “top view”. In the top view, a longitudinal direction and a lateral direction along a long-side edge and a short-side edge forming the outer contour of the rectangular mounting substrate 2 are referred to as the “longitudinal direction D1” and the “lateral direction D2”, respectively, as indicated by arrows in FIG. 2. The longitudinal direction D1 and the lateral direction D2 may also be regarded as a long-side direction and a short-side direction, respectively. Also in drawings other than FIG. 2, a longitudinal direction D1 and a lateral direction D2 indicated by arrows, respectively, correspond to the longitudinal direction D1 and the lateral direction D2 shown in FIG. 2. Further, the longitudinal direction D1 and the lateral direction D2, respectively, correspond to a longitudinal direction and a lateral direction of the semiconductor device 1. In FIG. 2, for the sake of clarity of each component disposed in a housing portion 61 of the molded resin 6, which will be described later, illustrations of the gel 9 and the lid member 11 are omitted, and the outer contours of the circuit chip 3 and an abutting portion 63, which will be described later, are indicated by dashed lines.

The circuit chip 3 is, for example, a semiconductor chip made of a semiconductor material such as silicon, and formed with an ASIC (not shown) used for driving control of the semiconductor element 7 and the like. ASIC is an abbreviation for Application Specific Integrated Circuit. The circuit chip 3 has a lower surface 3b, an upper surface 3a opposite to the lower surface 3b, and a side surface 3c connecting the upper surface 3a and the lower surface 3b. The circuit chip 3 is disposed so that the lower surface 3b faces the mounting substrate 2, and a part of the upper surface 3a and the side surface 3c are covered by the molded resin 6. The circuit chip 3 is disposed so that the semiconductor element 7 is arranged above the upper surface 3a and a part of the molded resin 6 is interposed between the semiconductor element 7 and the upper surface 3a. The circuit chip 3 is electrically connected to the mounting substrate 2 via the wire 5. The circuit chip 3 is electrically connected to the semiconductor element 7 via the wire 8. In the circuit chip 3, a part of an exposed area of the upper surface 3a exposed from the molded resin 6 serves as an electrical connection portion 31 that is electrically connected to the semiconductor element 7. In the circuit chip 3, for example, a part of the upper surface 3a that is electrically connected to the mounting substrate 2 is covered by the molded resin 6 together with the wire 5. In the present embodiment, as shown in FIG. 2, the circuit chip 3 has a planar size in a planar direction along the surface of the mounting substrate 2 that is larger than that of the semiconductor element 7. The term “planar size” refers to the size of an outer contour of a component in the top view, that is, as viewed from above. Hereinafter, the planar size in the planar direction along the surface of the mounting substrate 2 described above will be simply referred to as the “planar size”.

The adhering material 4 is disposed between the mounting substrate 2 and the circuit chip 3, and between the abutting portion 63 of the molded resin 6 and the semiconductor element 7, and serves to bond these components to each other. The adhering material 4 is made of, for example, an adhesive film such as a die attach film (DAF) or an adhesive such as a thermosetting resin.

The wires 5 and 8 are each made of a conductive material such as gold, silver, copper, or aluminum. The wires 5 and 8 are connected to the mounting substrate 2, the circuit chip 3, or the semiconductor element 7 by wire bonding. In the present embodiment, the wire 8 that connects the circuit chip 3 and the semiconductor element 7 is arranged such that its loop direction DL extends along the lateral direction D2. The loop direction DL refers to a direction that the wire 8 extends when viewed from above, that is, a direction in which the wire connects the circuit chip 3 and the semiconductor element 7. In addition, the phrase “the loop direction DL extends along the lateral direction D2” is not limited to a state in which the loop direction DL is parallel to the lateral direction D2, but also includes a state in which the loop direction DL intersects with the longitudinal direction D1.

For example, the molded resin 6 is made of an insulating thermosetting resin material, such as epoxy resin, and is formed by injection molding using a mold 100, which will be described later. The molded resin 6 includes the housing portion 61, a covering portion 62 and the abutting portion 63. The housing portion 61 defines a cavity or space for housing the semiconductor element 7 and the gel 9. The covering portion 62 covers a part of the upper surface 3a of the circuit chip 3. The abutting portion 63 protrudes from the covering portion 62, and the semiconductor element 7 is mounted on the abutting portion 63. The housing portion 61 defines a recess having a width and depth sufficient to accommodate the entire semiconductor element 7 therein. A part of the bottom surface of the housing portion 61 is provided by the covering portion 62, which covers a part of the upper surface 3a of the circuit chip 3, and the abutting portion 63.

The abutting portion 63 has an abutting surface 63a at its tip end surface, and the semiconductor element 7 is mounted on the abutting surface 63a. The semiconductor element 7 has a front surface 7a, and a back surface 7b opposite to the front surface 7a. The semiconductor element 7 is disposed so that the back surface 7b faces the circuit chip 3. The abutting surface 63a is smaller in the planar size than the back surface 7b of the semiconductor element 7. The abutting portion 63 keeps the semiconductor element 7 away from the circuit chip 3, which is a heat source, and a fixed area of the abutting surface 63a to the semiconductor element 7 is smaller than the area of the back surface 7b of the semiconductor element 7. As such, the abutting portion 63 serves to reduce the thermal effect on the semiconductor element 7. When the amount of protrusion of the abutting portion 63 from the upper surface 3a of the circuit chip 3 in the normal direction, that is, in the thickness direction, is referred to as the height of the abutting portion 63, the height of the abutting portion 63 is, for example, about 200 μm to 300 μm. However, the height of the abutting portion 63 is not limited to this range.

The semiconductor element 7 is made of a semiconductor material, such as silicon or silicon carbide, and is manufactured by a known semiconductor process. The semiconductor element 7 is, for example, a sensor element having a sensor portion (not shown) that outputs a signal corresponding to a predetermined physical quantity, such as acceleration or angular velocity, applied from the outside. For example, the semiconductor element 7 may be made of a single semiconductor chip, or may have a stacked structure in which two or more semiconductor chips are joined together. For example, the semiconductor element 7 may be configured as an IMU including an acceleration sensor and an angular velocity sensor. However, the semiconductor element 7 is not limited to this example. IMU is an abbreviation for Inertial Measurement Unit. The semiconductor element 7 has electrode pads (not shown) that are connected to the sensor portion on the front surface 7a side. The wires 8 are connected to the electrode pads of the semiconductor element 7, enabling the exchange of signals with the circuit chip 3. In the present embodiment, the semiconductor element 7 is disposed in an area inside the outer contour of the circuit chip 3 in the top view. For example, as shown in FIG. 2, two semiconductor elements 7 in total are mounted on a single circuit chip 3 via two abutting portions 63. However, the number of the semiconductor elements 7 can be changed as appropriate as long as the semiconductor element 7 is superposed and arranged on the circuit chip 3.

The gel 9 is, for example, a heat dissipation gel that is insulating and has high thermal conductivity. The gel 9 is disposed in the housing portion 61, and covers the circuit chip 3, the semiconductor element 7, and the wire 8. The bonding material 10 is used to bond the lid member 11 to the molded resin 6, and is made of an adhesive or the like. It should be noted that, when the lid member 11 is directly bonded to the molded resin 6 by laser welding or the like, the semiconductor device 1 does not need to have the bonding material 10.

The lid member 11 is a cover-shaped member that covers the housing portion 61 of the molded resin 6 and may also be referred to as a “lid”. The lid member 11 is, for example, a metal lid made of a metallic material. However, the lid member 11 is not limited to this example. The lid member 11 may be made of any other material, such as ceramic, that can be attached to the molded resin 6. A closed space formed by closing the housing portion 61 of the molded resin 6 with the lid member 11 is kept in an inert gas atmosphere such as nitrogen.

The semiconductor device 1 of the present embodiment has the basic configuration as described above. In the above description, the example in which the gel 9 is disposed in the housing portion 61 has been illustrated. However, the semiconductor device 1 is not limited to such an example, and may have a configuration without the gel 9.

### Manufacturing Method

Next, a method for manufacturing the semiconductor device 1 according to the present embodiment will be described. Here, a case where a plurality of semiconductor devices 1 are manufactured at once will be described as a representative example. However, the manufacturing method of the present disclosure is not limited to this example.

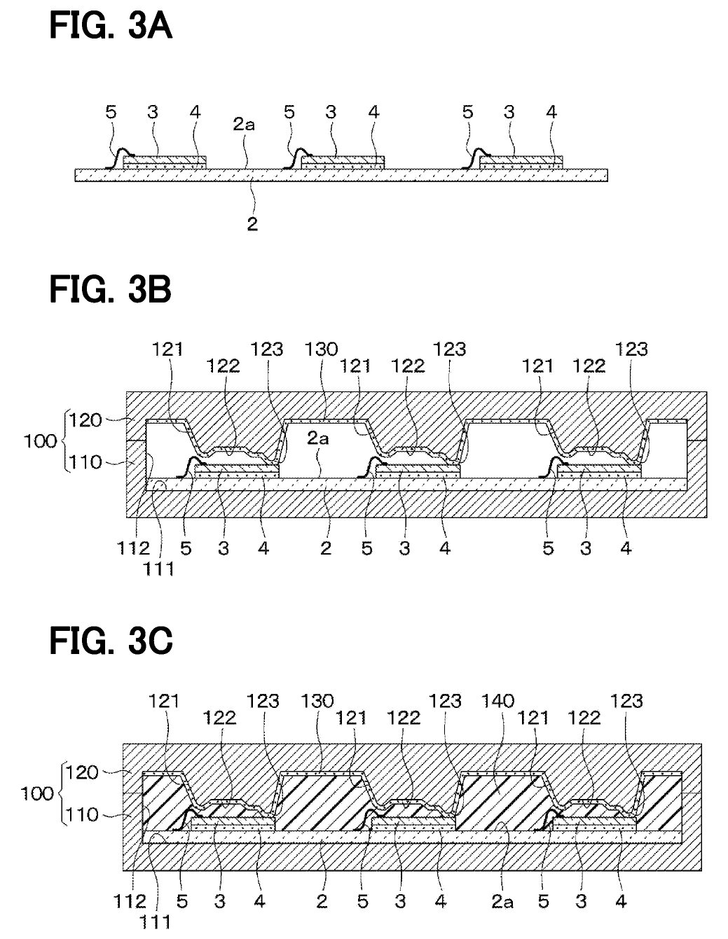

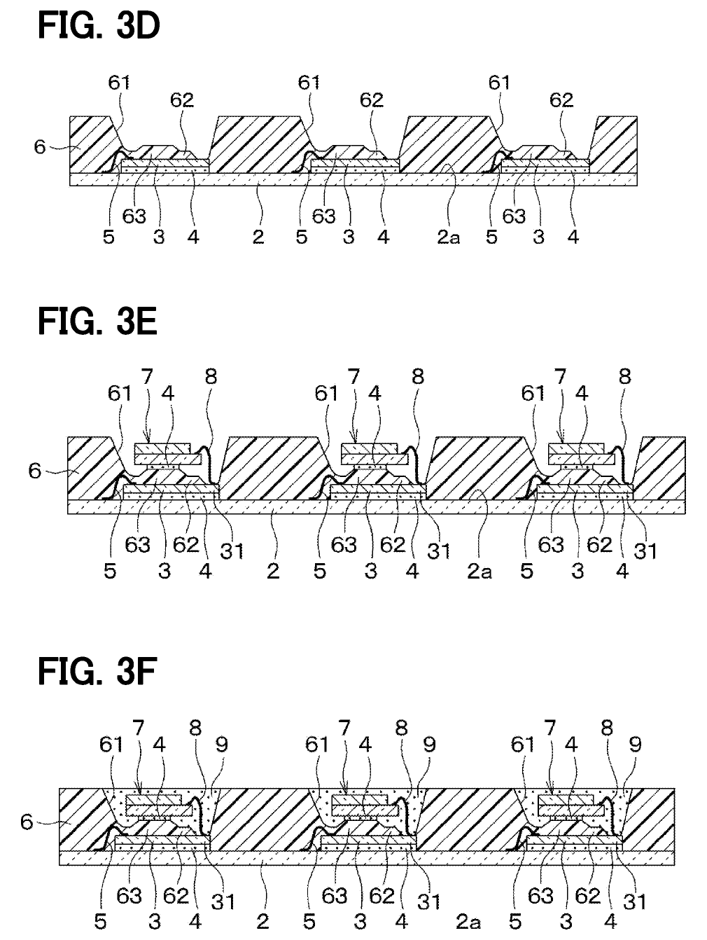

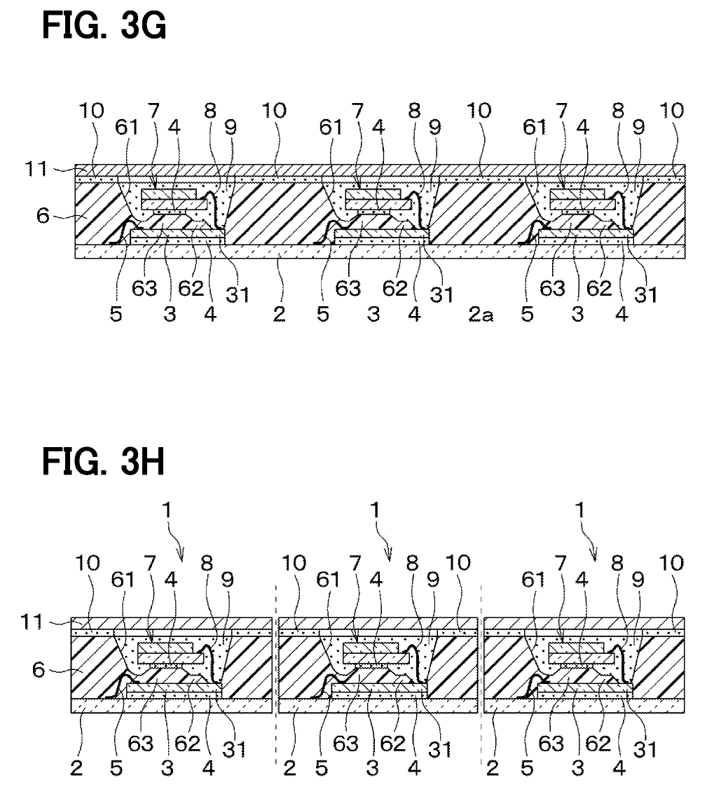

For example, as shown in FIG. 3A, the mounting substrate 2 and the plurality of circuit chips 3 are prepared. The plurality of circuit chips 3 are mounted on the mounting substrate 2 via the adhering material 4. Then, the wires 5 are connected to the mounting substrate 2 and the circuit chips 3 by wire bonding.

Next, as shown in FIG. 3B, for example, a mold 100 for molding the molded resin 6 is prepared, and a workpiece obtained in the process shown in FIG. 3A (hereinafter simply referred to as “the workpiece shown in FIG. 3A”) is set in the mold 100. The mold 100 is for injection molding of a resin material. For example, the mold 100 is made of a metal material, and includes a lower mold 110 and an upper mold 120. The lower mold 110 is formed with a recess 112 having a bottom surface 111 that is brought into contact with the mounting substrate 2 of the workpiece shown in FIG. 3A. The upper mold 120 is formed with a plurality of protrusions 121 that protrude toward the areas of the recess 112 of the lower mold 110 where the circuit chips 3 are to be placed. For example, each of the protrusions 121 is formed with a depressed portion 122 that covers a part of the upper surface 3a of the circuit chip 3 to form the abutting portion 63 of the molded resin 6, and a pressing portion 123 that is pressed against the electrical connection portion 31 of the circuit chip 3. The protrusion 121 has a shape that conforms to the outer shape of the housing portion 61 of the molded resin 6. The depressed portion 122 is formed at a facing surface of the protrusion 121 facing the circuit chip 3. The depressed portion 122 is depressed to be away from the circuit chip 3, and has a shape conforming to the outer shape of the abutting portion 63. The pressing portion 123 is formed at the facing surface of the protrusion 121 facing the circuit chip 3. The pressing portion 123 projects from the facing surface of the protrusion 121 toward the circuit chip 3, and covers the electrical connection portion 31.

It is preferable to attach a protective film 130 to the upper mold 120 in order to suppress damage to the circuit chip 3 due to the pressing portion 123 and to facilitate release of the molded resin 6 after molding. In this case, the pressing portion 123 comes into contact with the electrical connection portion 31 of the circuit chip 3 via the protective film 130, thereby to restrict the electrical connection portion 31 from being covered by the molded resin 6. The protective film 130 is made of, for example, a fluorine-based resin material. The protective film 130 is attached to a predetermined area of the upper mold 120 including the protrusions 121, for example, by vacuuming through an exhaust hole (not shown) formed in the upper mold 120, and is shaped to follow the outer shape of the protrusions 121.

Next, as shown in FIG. 3C, for example, a resin material 140 is injected into the space, i.e., the cavity of the mold 100 formed between the assembled lower mold 110 and upper mold 120, through an injection port (not shown) of the mold 100. After the cavity of the mold 100 is filled with the resin material 140, the resin material 140 is cured. Thus, the molded resin 6 is formed. A portion of the resin material 140 that fills a gap between the protrusion 121 and the circuit chip 3 becomes the covering portion 62 and the abutting portion 63, and the space occupied by the protrusion 121 becomes the housing portion 61. In this way, it is possible to form the molded resin 6 having the housing portion 61, the covering portion 62, and the abutting portion 63 on the mounting substrate 2 and the circuit chip 3.

Thereafter, as shown in FIG. 3D, for example, the workpiece on which the molded resin 6 has been formed is removed from the mold 100. Then, as shown in FIG. 3E, for example, the semiconductor element 7 is fixed onto the abutting portion 63 of the molded resin 6 via the adhering material 4. Subsequently, the wire 8 is connected to the electrical connection portion 31 of the circuit chip 3 and the electrode pad (not shown) of the semiconductor element 7 by wire bonding, thereby electrically connecting the circuit chip 3 and the semiconductor element 7.

Then, as shown in FIG. 3F, for example, the gel 9 is injected into the housing portion 61, so that the circuit chip 3, the semiconductor element 7, and the wire 8 are sealed with the gel 9. Subsequently, as shown in FIG. 3G, for example, the lid member 11 is joined to the molded resin 6 by using the bonding material 10 or any suitable method such as laser welding, thereby sealing the housing portion 61. Finally, as shown in FIG. 3H, for example, the workpiece is divided into individual pieces by dicing. In this way, the plurality of semiconductor devices 1 are produced.

In the semiconductor device 1 of the present embodiment, the semiconductor element 7 is stacked and arranged on the circuit chip 3. Thus, the planar size of the semiconductor device 1 is reduced, and the semiconductor device 1 is reduced in size. In addition, in the semiconductor device 1, since the semiconductor element 7 is arranged on the abutting portion 63 having a protruded structure, the thermal influence on the semiconductor element 7 from the circuit chip 3 is reduced, and the signal output from the semiconductor element 7 becomes stable. Furthermore, in the semiconductor device 1, the semiconductor element 7 has a hollow structure as being exposed from the molded resin 6 in the housing portion 61, or a covered structure covered with the gel 9 having a lower stress than the molded resin 6 in the housing portion 61. Therefore, it is possible to reduce the stress on the semiconductor element 7. The semiconductor device 1 has the following features.

(1) The area of the abutting surface 63a fixed to the back surface 7b of the semiconductor element 7 is smaller than the area of the back surface 7b of the semiconductor element 7 facing the circuit chip 3. As a result, the contact area between the semiconductor element 7 and the abutting surface 63a located above the heat source is reduced, and the thermal influence on the sensor portion (not shown) of the semiconductor element 7 can be decreased.

The manufacturing method of the semiconductor device 1 according to the present embodiment includes: forming the molded resin 6 that covers a part of the circuit chip 3 using the mold 100, and mounting the semiconductor element 7 on the abutting surface 63a after the forming of the molded resin 6. In the forming of the molded resin 6, the mold 100 is used that has the protrusion 121 protruding toward the circuit chip 3, the depressed portion 122 recessed to be away from the circuit chip 3 in the protrusion 121, and the pressing portion 123 that comes into contact with the electrical connection portion 31 in the protrusion 121. The housing portion 61 and the abutting portion 63 of the molded resin 6 are formed by the protrusion 121 and the depressed portion 122. Furthermore, the electrical connection portion 31 is exposed in the housing portion 61 of the molded resin 6. In this way, it is possible to manufacture the semiconductor device 1 that is miniaturized and in which the stress and the thermal influence on the semiconductor element 7 are suppressed.

### Second Embodiment

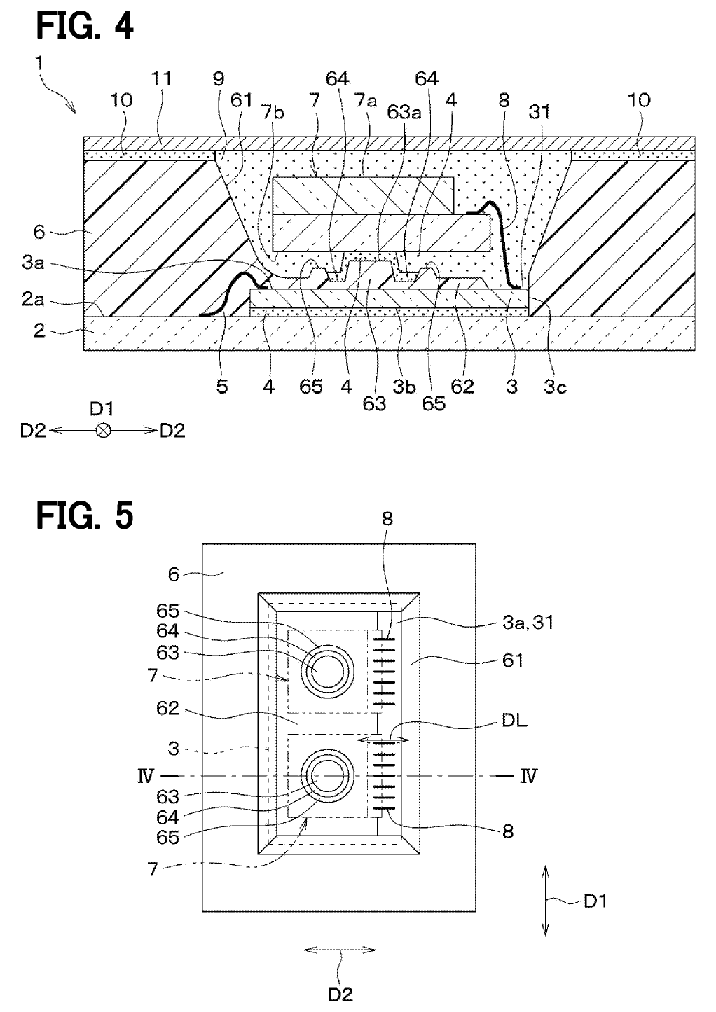

A semiconductor device 1 according to a second embodiment will be described. As shown in FIG. 4, for example, the semiconductor device 1 of the present embodiment is different from the semiconductor device 1 of the first embodiment in that the adhering material 4, which bonds the abutting portion 63 to the semiconductor element 7, is made of an adhesive, and the covering portion 62 has an uneven structure in the vicinity of the abutting portion 63. Hereinafter, these differences will be mainly described. FIG. 4 is a cross-sectional view taken along a line IV-IV of FIG. 5.

In the present embodiment, as shown in FIG. 5, for example, the covering portion 62 has the uneven structure that separates the abutting portion 63 and the electrical connection portion 31 of the circuit chip 3 from each other. It should be noted that, in FIG. 5, similarly to FIG. 2, illustrations of the gel 9 and the lid member 11 are omitted. Also, the outer contour of the semiconductor element 7 is indicated by a two-dot chain line, and the outer contours of the abutting portion 63 and the uneven structure are indicated by solid lines. The uneven structure is composed of, for example, a recessed portion 64 and a projected portion 65. For example, the recessed portion 64 is an annular groove positioned closer to the abutting portion 63 than the projected portion 65. The recessed portion 64 is configured to receive an excess portion of the adhering material 4. For example, the projected portion 65 is an annular projection surrounding the recessed portion 64. The projected portion 65 is configured to block the adhering material 4 that has flowed into the recessed portion 64, thereby to restrict the adhering material 4 from reaching the electrical connection portion 31. As shown in FIG. 4, the projected portion 65 is lower in height than the abutting portion 63. In other words, the uneven structure is provided to protect the electrical connection portion 31 of the circuit chip 3 from the adhering material 4 used to bond the semiconductor element 7. The recessed portion 64 and the projected portion 65 are provided in a region of the covering portion 62 that is located inside the outer contour of the semiconductor element 7 in the top view.

It should be noted that the covering portion 62 of the present embodiment is not limited to the example described above as long as it has the structure capable of restricting the adhering material 4 from flowing to the electrical connection portion 31. The recessed portion 64 and the projected portion 65 may have any shapes, other than the annular shape, in the top view. For example, the recessed portion 64 and the projected portion 65 may have a frame shape other than a circle, in the top view. The recessed portion 64 and the projected portion 65 may have a linear shape, curved shape, or a combination thereof, to separate the abutting surface 63a and the electrical connection portion 31. That is, the shapes of the recessed portion 64 and the projected portion 65 may be modified in various ways. Furthermore, the covering portion 62 may be configured to have only one of the recessed portion 64 and the projected portion 65 in the vicinity of the abutting portion 63.

The semiconductor device 1 according to the second embodiment also achieves the advantageous effects similar to those of the first embodiment.

### Third Embodiment

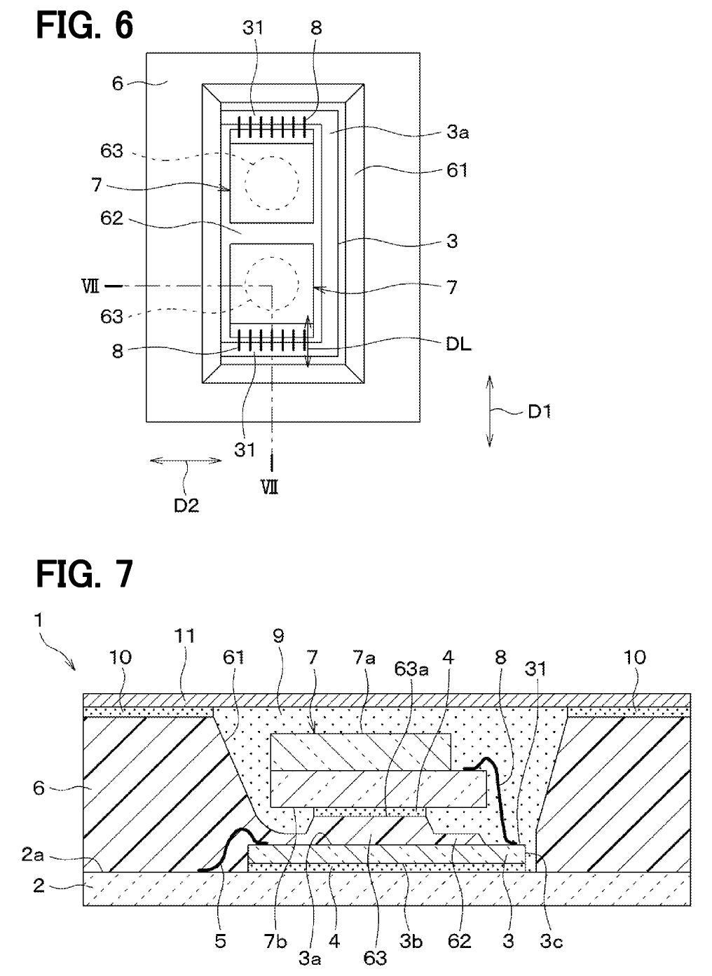

A semiconductor device 1 of a third embodiment will be hereinafter described. The semiconductor device 1 of the present embodiment is different from the semiconductor device 1 of the first embodiment in that a part of the side surface 3c of the circuit chip 3 is exposed from the molded resin 6, and the loop direction DL of the wire 8 is changed, as shown in FIG. 6, for example. Hereinafter, these differences will be mainly described. It should be noted that, in FIG. 6, similarly to FIG. 2, the outer contour of the abutting portion 63 is shown with a dashed line, and illustrations of the gel 9 and the lid member 11 are omitted.

In the present embodiment, in the top view, of the four sides of the side surface 3c, which forms the outer contour of the circuit chip 3, three sides, other than one side covered by the covering portion 62, are exposed from the molded resin 6. For example, immediately after the molded resin 6 is formed, the entire side surface 3c of the circuit chip 3 is covered by the molded resin 6. By removing at least a part of the portion of the molded resin 6 that covers the side surface 3c by laser irradiation, three sides of the side surface 3c are exposed from the molded resin 6. As shown in FIG. 7, for example, the semiconductor device 1 has a structure in which a part of the side surface 3c of the circuit chip 3 is exposed and free from the molded resin 6. As a result, the influence of deformation of the mounting substrate 2 is less likely to be transmitted to the upper part of the circuit chip 3. Therefore, the signal output of the semiconductor element 7 is stabilized and the sensor accuracy is improved.

In the present embodiment, the plurality of wires 8 are connected to the circuit chip 3 and the semiconductor element 7 at predetermined intervals such that the loop direction DL extends along the longitudinal direction D1 of the semiconductor device 1. In other words, in the semiconductor device 1, an imaginary straight line connecting the electrical connection portion 31 of the circuit chip 3 and the electrode pad (not shown) of the semiconductor element 7 is aligned with the longitudinal direction D1 of the mounting substrate 2. It should be noted that the phrase “the loop direction DL extends along the longitudinal direction D1” is not limited to a state in which the loop direction DL is parallel to the longitudinal direction D1, but also includes a state in which the angle formed between the loop direction DL and the longitudinal direction D1 is 45 degrees or less. As a result, when the mounting substrate 2 warps along the longitudinal direction D1, the change in the spacing between the plurality of wires 8, which are bent due to the warpage of the mounting substrate 2, is suppressed. As such, it is possible to achieve the effect of suppressing variations in parasitic capacitance between the circuit chip 3 and the semiconductor element 7.

The semiconductor device 1 of the present embodiment can also achieve the similar effects to those in the first embodiment described above. In addition, in the semiconductor device 1 of the present embodiment, the part of the side surface 3c of the circuit chip 3 is exposed and released from the molded resin 6 in the housing portion 61. Therefore, it is possible to restrict the influence due to the deformation of the mounting substrate 2 from being transmitted to the upper part of the circuit chip 3. Furthermore, in the semiconductor device 1 of the present embodiment, the loop direction DL of the plurality of wires 8 is aligned with the longitudinal direction D1. Therefore, the changes in the spacing between the wires 8 due to the bending of the wires 8 caused by the warpage of the mounting substrate 2 are suppressed, and consequently, variations in parasitic capacitance are suppressed.

### Fourth Embodiment

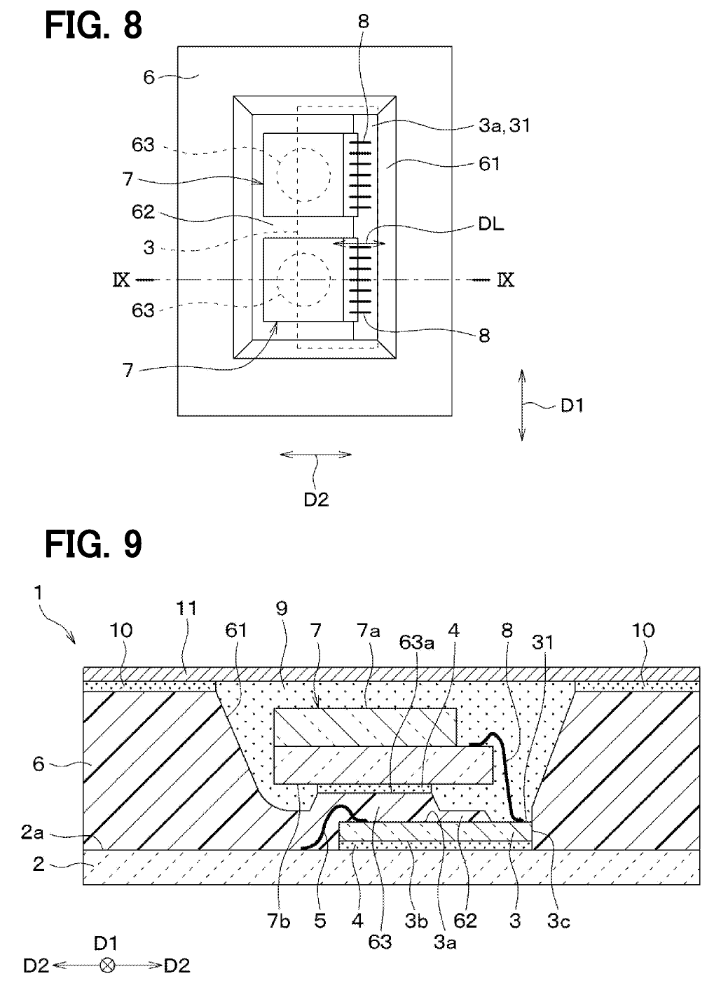

A semiconductor device 1 of a fourth embodiment will be hereinafter described. The semiconductor device 1 of the present embodiment is different from the semiconductor device 1 of the first embodiment described above in that the size of the circuit chip 3 is relatively small, as shown in FIG. 8, for example. Hereinafter, this difference will be mainly described.

In the present embodiment, as shown in FIG. 9, for example, the width of the circuit chip 3 in the lateral direction D2 is equal to or less than the width of the semiconductor element 7 in the lateral direction D2. In the present embodiment, the wire 5 that connects the circuit chip 3 to the mounting substrate 2 is covered by the abutting portion 63. When the size of the circuit chip 3 is reduced for miniaturization, the arrangement is adjusted so that the wire 5 connecting the mounting substrate 2 and the circuit chip 3 is positioned directly beneath the abutting portion 63. As such, the semiconductor device 1 has a package structure similar to the basic structure of the first embodiment. That is, even when the circuit chip 3 is reduced in size, the semiconductor device 1 of the present embodiment can achieve the similar effects to those in the first embodiment described above. It should be noted that, although the configuration in which the width of the circuit chip 3 is equal to or less than the width of the semiconductor element 7 in one direction along the lateral direction D2 has been illustrated as a representative example, the present disclosure is not limited to such a configuration. For example, the circuit chip 3 and the semiconductor element 7 may have the width relationship described above in another direction, such as in the longitudinal direction D1.

The semiconductor device 1 of the present embodiment can also achieve the similar effects to those in the first embodiment. In addition, the semiconductor device 1 of the present embodiment has a structure that can also be adopted in cases where a small circuit chip 3 is used.

### Other Embodiments

The present disclosure has been described in accordance with embodiments, but it is to be understood that the present disclosure is not limited to these embodiments or structures. The present disclosure also encompasses various modifications and alterations within the scope of equivalents. In addition, various combinations and forms, as well as other combinations and forms that include only one element thereof, more, or less, also fall within the scope and spirit of the present disclosure.

The constituent element(s) of each of the embodiments described above is/are not necessarily essential unless it is specifically stated that the constituent element(s) is/are essential in the above embodiment, or unless the constituent element(s) is/are obviously essential in principle. A quantity, a value, an amount, a range, or the like referred to in the description of the embodiments described above is not necessarily limited to such a specific value, amount, range or the like unless it is specifically described as essential or understood as being essential in principle. In each of the embodiments described above, when referring to the shape, positional relationship, and the like of the constituent elements and the like, the shape, positional relationship, and the like are not limited unless otherwise specified or limited to a specific shape, positional relationship, and the like in principle.

What is claimed is:

1. A semiconductor device, comprising:
a semiconductor element having a sensor portion that outputs a signal corresponding to a physical quantity applied thereto;
a circuit chip having an electrical connection portion electrically connected to the semiconductor element; and
a molded resin having a housing portion that defines a space for housing the semiconductor element, a covering portion that covers a part of the circuit chip in the housing portion, and an abutting portion that protrudes from the covering portion and has an abutting surface,
wherein the semiconductor element is mounted on the abutting surface above the circuit chip, and
wherein the semiconductor element and the electrical connection portion are exposed from the molded resin in the housing portion.

2. The semiconductor device according to claim 1,
wherein the semiconductor element has a back surface facing the circuit chip and fixed to the abutting surface, and
wherein an area of the abutting surface fixed to the back surface of the semiconductor element is smaller than an area of the back surface of the semiconductor element.

3. The semiconductor device according to claim 2,
wherein the semiconductor element is bonded to the abutting surface with an adhesive, and
wherein the covering portion has at least one of a recessed portion or a projected portion so as to separate the abutting portion and the electrical connection portion from each other.

4. The semiconductor device according to claim 3,
wherein the semiconductor element is electrically connected to the circuit chip by a wire,
wherein a direction in which the wire connects the semiconductor element and the circuit chip is referred to as a loop direction, and
wherein the wire is arranged such that the loop direction extends along a longitudinal direction of the semiconductor device.

5. The semiconductor device according to claim 1,
wherein the circuit chip has an upper surface facing the semiconductor element, a lower surface opposite to the upper surface, and a side surface connecting the upper surface and the lower surface, and
wherein the side surface of the circuit chip is exposed from the molded resin in the housing portion at least at a part that is different from a part covered by the covering portion.

6. The semiconductor device according to claim 1, further comprising:
a mounting substrate on which the circuit chip is mounted,
wherein the circuit chip is electrically connected to the mounting substrate by a wire,
wherein a width of the semiconductor element in at least one direction along a plane of the mounting substrate is equal to or greater than a width of the circuit chip in the at least one direction, and
wherein the wire is covered by the abutting portion.

7. A method for manufacturing a semiconductor device, the semiconductor device including:
a semiconductor element having a sensor portion that outputs a signal corresponding to a physical quantity applied thereto; and
a circuit chip having an electrical connection portion electrically connected to the semiconductor element; and
a molded resin having a housing portion that defines a space for housing the semiconductor element, a covering portion that covers a part of the circuit chip in the housing portion, and an abutting portion that protrudes from the covering portion and has an abutting surface on which the semiconductor element is mounted above the circuit chip,
the method for manufacturing the semiconductor device, comprising:
forming the molded resin that covers a part of the circuit chip using a mold; and
after the forming of the molded resin, mounting the semiconductor element on the abutting surface,
wherein the mold, which is used in the forming of the molded resin, has a protrusion protruding toward the circuit chip, a depressed portion provided on the protrusion and recessed away from the circuit chip, and a pressing portion provided on the protrusion and coming into contact with the electrical connection portion, and
wherein the forming of the molded resin using the mold includes:
forming the housing portion and the abutting portion of the molded resin by the protrusion and the depressed portion of the mold; and
causing the electrical connection portion to be exposed from the molded resin in the housing portion.

8. The method according to claim 7,
wherein, in the forming of the molded resin, the mold has a protective film covering at least the protrusion, the depressed portion, and the pressing portion, and
wherein the forming the molded resin includes:
causing the pressing portion to come into contact with the electrical connection portion via the protective film.
